(19) United States
(12) Patent Application Publication
(10) Pub. No.: US 2010/0132987 A1
(43) Pub. Date: Jun. 3, 2010

(54) METHOD FOR PRODUCING AN ELECTRICALLY CONDUCTIVE PATH ON A PLASTIC COMPONENT

(76) Inventor: Nikolaus Hautmann, Ditzingen (DE)

Correspondence Address: KENYON & KENYON LLP, ONE BROADWAY, NEW YORK, NY, 10004, US

(21) Appl. No.: 12/450,045

(22) PCT Filed: Feb. 8, 2008
(86) PCT No.: PCT/EP2008/051531

§ 371 Date: Feb. 23, 2010

(30) Foreign Application Priority Data
Mar. 27, 2007 (DE) 102007014501.4

(51) Int. Cl. H05K 1/09; H05K 3/00

(52) U.S. Cl. 174/257; 427/98.4

(57) ABSTRACT

In a method for producing an electrically conductive path on a plastic component, the plastic material of the plastic component is converted into a conductive substance using an energy application that is guided along the path.

### BACKGROUND OF THE INVENTION

1. Field of the Invention

The present invention relates to a method for producing an electrically conductive path on a plastic component. The present invention also relates to an electric circuit having an electrically conductive path, the electric circuit being situated on a plastic substrate.

2. Description of Related Art

Electronic circuits occur in all fields of modern life. Especially in motor vehicle technology, many sensors and actuators are used in modern vehicles that have to be sealed and encased from their environment, to protect them from the influence of atmospheric conditions. Particularly on their inside, these components require current bars in the widest sense, since on their insides various components have to be connected to one another, and/or a current line is required in general. In the related art, lead wires, printed-circuit traces made of the most different metals, especially copper, wires, etc., of all possible geometries are used for this. What is disadvantageous in doing this is that these current bars or conductors do not bond with their surroundings: as a result, the components are not sealed along these conductors. Based on the different coefficients of expansion, tensions and perhaps cracks occur at the boundary surfaces of the conductors. The additional conductors frequently have to be produced in their own tool, thus, for instance, current bars are punched out and mounted separately into the component parts.

### BRIEF SUMMARY OF THE INVENTION

It is an object of the present invention to provide a method for producing electrically conductive paths on a plastic component part, which avoids the disadvantages explained above.

For this purpose, a method is proposed for producing an electrically conductive path on a plastic component, it being provided that the plastic material of the plastic component be converted into a conductive substance using the application of energy running along the path. Accordingly, in a manner that is different from the related art, no conductor is mounted on the plastic component (which approximately fulfills the function of a printed-circuit board or is one), but the electrically conductive path is generated on the plastic component itself. The separately mounted conductor is accordingly replaced by a conductive layer of plastic components (namely, of such as are able to be obtained from the plastic material of the plastic component). There is consequently present a conductor that is integrated into the surface of the plastic component. Because of the application of high energy taking place along the path (the application of energy taking place essentially perpendicularly to the surface of the plastic component, and along the path that is to be produced), the (insulating) plastic material of the plastic component is decomposed to form electrically conductive carbon compounds at the surface, in the area of the application. A conductive layer is “burned into” the plastic material of the plastic component, so to speak. Plastics are made up essentially of carbon compounds, which are decomposed by the application of electric stress and, especially, by spark discharge, so that an electrically conductive carbon compound remains in the area of action of the application of energy. And, because the energy application, acting essentially perpendicularly to the path, is guided along the path, there comes about a continuous conversion of the plastic material to form electrically conductive carbon compounds at the surface of the plastic component.

In one example embodiment of the method it is provided that the application of energy takes place by spark discharge. As a result, the application of energy is made by exposing the plastic material of the plastic component to a strong electrical field, the plastic component, as such, being grounded, and above it, in the area of the desired path, a strong electric field being applied via an electrode that is at a distance from the plastic component, which causes spark discharge to take place between the electrode and the plastic component in the area of the path. Because of the action of the spark arc-over, the plastic material of the plastic component is decomposed at its surface in the area of the spark discharge, to form electrically conductive carbon compounds.

In another example embodiment, the energy application takes place using a laser application. A laser beam rich in energy and especially focused, is guided along the desired path in such a way that it “burns”, so to speak, the plastic material, that was insulating up until then, along the path and at a desired depth and/or width, so that electrically conductive carbon compounds and carbons remain left over which develop the cohesive electrically conductive path. The use of an (especially focused) laser beam, compared to the use of a spark discharge, has the advantage that the plastic component itself does not have to be grounded, and the development of a strong electric field (that also has to be otherwise monitored and controlled) having the typical risks, becomes unnecessary. At the same time, a corresponding laser having sufficiently high power is extraordinarily rapid in its processing speed, so that the process of producing the electrically conductive path is able to proceed in a speeded up manner.

In one example embodiment it is provided that the depth of the path is set using the duration of the spark discharge. The duration of the acting of the spark discharge on a certain area of the surface of the plastic component decisively influences the increase in the conversion of the plastic material to conductive carbon compounds. This particularly has the influence as to the depth of the plastic component to which this decomposition takes place. If the electric field and the spark discharge act for a longer time on a specific area of the surface of the plastic component, a more vigorous conversion takes place, and especially so does a greater depth extension of the conversion in the plastic component. The actually effective, current carrying capacity cross section of the electrically conductive path accordingly becomes greater the longer the duration of the spark discharge per path length unit. In this way one may produce an electrically conductive path that is exactly tailored to the required current carrying capacity, without separate components, such a copper conductors having to be applied.

Furthermore, an electric circuit having an electrical path is proposed, which has been produced as in the method according to one or more of the preceding claims. Electric circuits, produced by the present method, have the advantage of circuit-board traces integrated into the plastic material of the plastic component, namely, conductive paths which make separate printed-circuit traces, which make separate circuit-board traces, of the kind known from the related art, or wire connections, completely superfluous. In particular, intermediate layers for promoting adhesion between conductor or printed-circuit trace and plastic also become superfluous. The electric circuit is extraordinarily cost-effective to produce, since the conductive path is obtained from the plastic material of the plastic component that is present anyway, by conversion in an electric field, using spark discharge. Moreover, a very simple contacting of the electric circuit is possible, particularly by crimping or pressing, so that other types of contacts, for instance, to the outside, may be produced easily and cost-effectively.

An electric circuit having an electrically conductive path is also proposed, the electric circuit being situated on a plastic substrate, and the plastic substrate having the electrically conductive path that is created by conversion of the plastic material, using an energy application guided along the path, particularly a spark discharge or a laser application. Accordingly, the plastic substrate has the abovementioned electrically conductive path, the electric circuit being situated on the plastic substrate, and in this instance being contacted to the path, for example, directly, by applying contact elements of the electrical components to the electrically conductive path.

Another example embodiment of the electric circuit provides that the electric circuit is provided with compression regions for compression to produce contacts of the electrical path to contact partners. For contacting contact partners which, for example, may be components or contact connections to the outside, regions are accordingly provided at which regions of the contact partners are brought electrically conductively into a facing position to the electrically conductive path by the action of force, namely, compression, and are thus connected.

In one additional example embodiment of the electric circuit, it is provided that the electric circuit is injection molded or encapsulated. For this, hermetic sealing is achieved.

### BRIEF DESCRIPTION OF SEVERAL VIEWS OF THE DRAWING

FIG. 1 shows a schematic representation of the electric stress application to a plastic component using an electric field and spark discharge for producing an electrically conductive path.

FIG. 2 shows the contacting of contact partners to the electrically conductive path.

### DETAILED DESCRIPTION OF THE INVENTION

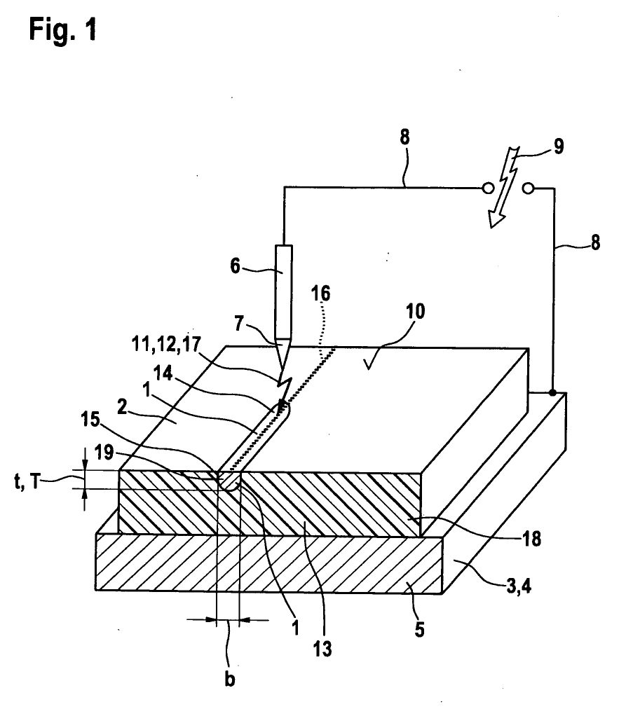

FIG. 1 shows a schematic representation of the method for producing an electrically conductive path 1 on a plastic component 2. To do this, plastic component 2 is placed on an electrically conductive carrier 3, foe instance, a metal plate 4. In this instance, carrier 3 forms an electrical antipole 5 to an electrical conductor 6, that is situated displaceably above plastic component 2, and that is preferably developed in the form of a spark tip 7 or has a spark tip 7. Between antipole 5 and spark tip 7, an electric field is generated, particularly via a high voltage generator 9 that is connected using electrical connections 8. Since plastic component 2 is conductively lying upon antipole 5, the electric field forms between spark tip 7 and a top side 10 of plastic component 2. If the field strength is sufficiently high, the striking of a spark 11 occurs between spark tip 7 and plastic component 2, in such a way that an electrical spark 12 is applied to top side 10 of plastic component 2. Because of this application of electric stress to plastic component 2 over its top side 10, plastic substrate 13, of which plastic component 2 is made, is converted into an electrically conductive carbon compound 15, in a spark area 14. The expansion of carbon compound 15 within plastic component 2, that is, particularly, depth expansion t (of a depth T) and width expansion b are determined, in this instance, by the strength of the electric field, and especially by the duration of the action of the electric field or the striking of the spark on top side 10. The longer spark area 14 is exposed to striking of spark 11, the deeper depth expansion t becomes, and, as a function of distance, so does the width expansion b of the conversion of plastic substrate 13 to electrically conductive carbon compounds 15. Using this, one is able to determine and regulate the current carrying capacity of the electrically conductive path, that is, via the duration of action of the electric field, since a longer duration of action brings about a greater depth expansion t and a greater width expansion b than a shorter duration of action, a bigger electrically conductive path 1 in cross section being developed than in response to a shorter duration of action. Meanwhile, the greater the cross section of electrically conductive path 1, the greater is its current carrying capacity. Accordingly, for the development of electrically conductive path 1 over the top side of plastic component 2, current tip 7 is guided along a current route 16, which is to be reformed to form electrically conductive path 1, while the electric field is being applied, that is, while high voltage generator 9 is active. During the guiding along of spark discharge 17 thus effected, plastic material 18 is converted to an electrically conductive substance 19 along current route 16. Electrically conductive substance 19 along current route 16 then develops electrically conductive path 1. What is advantageous in this, is that electrically conductive path 1 extends into the depth of plastic component 2, and consequently runs essentially or completely flush with top side 10 of plastic component 2. No separate components, such as printed-circuit traces, are required. Current route 16 may, in this instance, be guided essentially as desired over top side 10 of plastic component 2; in particular, if necessary, any crossing points or branchings of the current path may be produced by simply having a plurality of electrically conductive paths 1 cross one another. By applying differently strong electric fields to plastic component 2, it is possible, in particular, to develop differently dimensioned electrically conductive paths 1 on one and the same plastic component 2, that is, for example, large cross section main current paths and lesser cross section, finer branched connecting paths (not shown here for the sake of clarity).

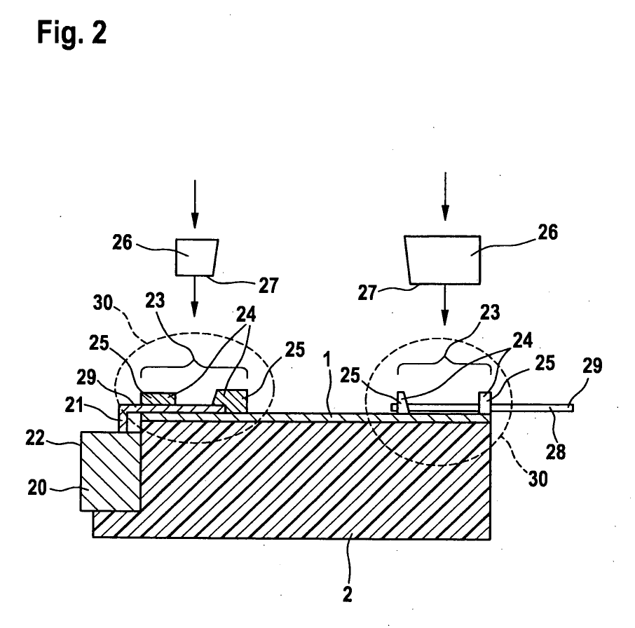

FIG. 2 shows the contacting of contact partners 29, for example, of components 20 on plastic component 2, which has electrically conductive path 1 for this purpose. Component 20 is provided for this with connecting contacts 21 which extend through a component housing 22 and lie upon an electrically conductive path 1 over an area 23. In the vicinity of area 23 of connecting contacts 21, plastic component 2 has clamping holders 24, which may, for instance, be made up of two clamping fixtures 25 which are developed essentially as little blocks, and which are situated at a distance from each other, in such a way that, between clamping fixtures 25 a clamping counterpart 26 is able to be used in such a way that it wedges between clamping fixtures 25 and, in the process, strikes with its bottom side 27 area 23 of connecting contacts 21 of component 20, at least in sections. Using compression regions 30 developed in this way, this produces a sufficiently secure contact position between region 23 and electrically conductive path 1. This makes soldering connections or similar laborious electrical connections unnecessary. In the same way, rectangular connector reeds 28 are able to be fixed, for connection in an electrically conductive manner, using a connector (that is not shown). For this purpose, rectangular connector reed 28, as was described above for connecting contacts 21, is laid upon electrically conductive path 1, and, directly adjacent, preferably on both sides of rectangular connector reed 28, a clamp holder 24 is developed. Between two clamping fixtures 25 that make clamping holder 24 work, a form-matched clamping counterpart 26 is mounted in clamped fashion, so that the application of force on rectangular connector reed 28 comes about, and with that, an electrically conductive contact position to electrically conductive path 1. Clamping holders 24, and particularly clamping counterparts 26, are illustrated in greatly exaggerated fashion, in this instance, for the sake of clarity of the illustration.

The electrical connection between electrically conductive path 1 and connecting contacts 21, or rectangular connector reed 28 or other, similar electrical conductors, is accordingly produced by compression. As a result, such contact partners 29 are not soldered, but laid on top and pressed onto electrically conductive path 1 by the application of force, and fixed in an electrically conductive manner.

1-8. (canceled)

9. A method for producing an electrically conductive path, comprising:
providing a plastic component; and
converting a plastic material of at least a portion of the plastic component into a conductive substance by applying energy along a path on the plastic component.

10. The method as recited in claim 9, wherein the depth of the path is set by controlling a time duration of the application of energy.

11. The method as recited in claim 9, wherein the application of energy is achieved by an electrical spark discharge.

12. The method as recited in claim 9, wherein the application of energy is achieved by a laser beam.

13. An electric circuit device produced according to a method comprising:
providing a plastic component; and
converting a plastic material of at least a portion of the plastic component into an electrically conductive path by applying energy along a path on the plastic component.

14. The electric circuit device as recited in claim 13, wherein the electrically conductive path is generated by converting the plastic material by application of one of a spark discharge or a laser beam.

15. The electric circuit device as recited in claim 14, wherein the electric circuit device includes compression regions configured for compression to produce contact of the electrically conductive path to a contact partner.

16. The electric circuit device as recited in claim 14, wherein the electric circuit device is one of injection molded or encapsulated.
